(19) United States
(12) Patent Application Publication
(10) Pub. No.: US 2009/0281744 A1
(43) Pub. Date: Nov. 12, 2009

(54) TESTING DEVICES

(76) Inventors: Cheng-Yung Teng, Taipei County (TW); Li-Jieu Hsu, Taipei City (TW)

Correspondence Address: Muncy, Geissler, Olds & Lowe, PLLC, P.O. BOX 1364, FAIRFAX, VA, 22038-1364, US

(21) Appl. No.: 12/430,648

(22) Filed: Apr. 27, 2009

(30) Foreign Application Priority Data
May 9, 2008 (TW) 097208070

(51) Int. Cl. G01R 19/155; G01R 29/02

(52) U.S. Cl. 702/64; 702/79

(57) ABSTRACT

A testing device for testing a device under test is disclosed. The testing device includes a microprocessor, a measuring module and a computing module. The microprocessor provides a testing signal to the device under test and determines a testing result for the device under test according to at least one signal measurement result. The device under test further generates at least one measuring signal after receiving the testing signal. The measuring module is coupled to the device under test, and measures the at least one measuring signal and generates at least one voltage measurement result and at least one period measurement result. The computing module obtains the at least one voltage measurement result and the at least one period measurement result according to a predetermined manner and generates the at least one signal measurement result.

### CROSS REFERENCE TO RELATED APPLICATIONS

This Application claims priority of Taiwan Patent Application No. 097208070, filed on May 9, 2008, the entirety of which is incorporated by reference herein.

### BACKGROUND OF THE INVENTION

1. Field of the Invention

The invention relates to a testing device and in particular to a testing device which tests the gain and voltage offset of a device under test.

2. Description of the Related Art

The popularity of integrated circuits (IC) has increased with the development of technology. Generally, each IC is tested after fabrication to ensure the quality of each IC. Thus, manufacturers determine whether the ICs are qualified according to the test results.

For mass production of ICs, the ICs are tested using a logic tester. Thus, there are different types of logic testers for different types of ICs. FIG. 1 is a diagram of a testing structure for a conventional D-type amplifier IC. A general D-type amplifier IC 14 is usually tested with an appropriate tester 12, such as an analog signal tester or audio logic tester. After the tester 12 provides a testing signal S_{T} to the D-type amplifier IC 14, the D-type amplifier IC 14 generates a pulse width modulations (PWM) signal which corresponds to the testing signal. Following, the PWM signal is transformed into a sine wave signal through a transformation module 16. Next, the appropriate tester 12 determines the testing result of D-type amplifier according to the sine wave signal received from transformation module 16. Thus, the testing structure for D-type amplifier IC 14 is shown.

The D-type amplifier IC 14 has two sound channels, a right sound channel and a left sound channel. The two sound channels have two output ports ROUT+, ROUT−, LOUT+ and LOUT−, respectively. The signal generated from the two output ports of the right sound channel ROUT+ and ROUT− is illustrated as follows as an example. For testing a voltage offset of the output ports ROUT+ and ROUT− of the right sound channel, a testing signal S_{T} having an input voltage with zero volts(V), is firstly inputted to the D-type amplifier IC 14 which provides integrated voltages V_{ROUT+} and V_{ROUT-} from two outputs ROUT+ and ROUT− of the right sound channel to the transformation module 16 in response to the testing signal. The integrated voltage VROUT+ is subtracted from the integrated voltage VROUT− to obtain the voltage offset of the right sound channel of D-type amplifier IC 14.

For measurement of the voltage gain of the two sound channels ROUT+ and ROUT− of D-type amplifier IC 14, the appropriate tester 12 provides an input voltage to the D-type amplifier IC 14 to acquire integrated voltages. V_{ROUT+} and V_{ROUT-}. The integrated voltage VROUT+ is subtracted from integrated voltage VROUT− to obtain an output voltage of the right sound channel. The output voltage is divided by input voltage to obtain the voltage gain of the right sound channel of the D-type amplifier IC 14.

However, the appropriate tester of a D-type IC is very expensive. Thus, a logic tester that can test ICs in a more convenient, efficient and less costly manner is desired.

### BRIEF SUMMARY OF THE INVENTION

Therefore, an objectives of the present invention is to provide a more convenient to use testing device that reduces testing costs and mitigates the above-mentioned problems.

A testing device for testing a device under test is provided. The testing device comprises a microprocessor, a measure module and a computing module. The microprocessor provides a testing signal to the device under test and determines a testing result for the device under test according to at least one signal measurement result. The device under test further generates at least one measuring signal after receiving the testing signal. The measuring module is coupled to the device under test and measures the at least one measuring signal and generates at least one voltage measurement result and at least one period measurement result. The computing module obtains the at least one voltage measurement result and the at least one period measurement result according to a predetermined manner and generates the at least one signal measurement result.

### BRIEF DESCRIPTION OF THE DRAWINGS

The invention can be more fully understood by reading the subsequent detailed description and examples with references made to the accompanying drawings, wherein:

FIG. 1 is a block diagram of a testing structure of a conventional D-type amplifier IC.

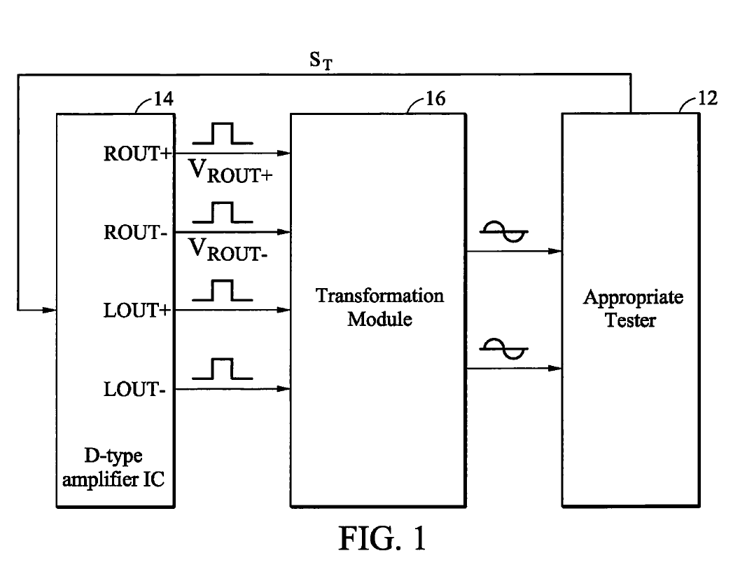

FIG. 2 is a schematic diagram of the testing device testing the device under test according to an embodiment of the invention.

FIG. 3 is a block diagram of at least one measuring signal of testing device according to an embodiment of the invention.

FIG. 4 is a schematic diagram of the testing device testing the device under test according to another embodiment of the invention.

FIG. 5 is a schematic diagram of the first measuring signal and the second measuring signal of the testing device according to an embodiment of the invention.

### DETAILED DESCRIPTION OF THE INVENTION

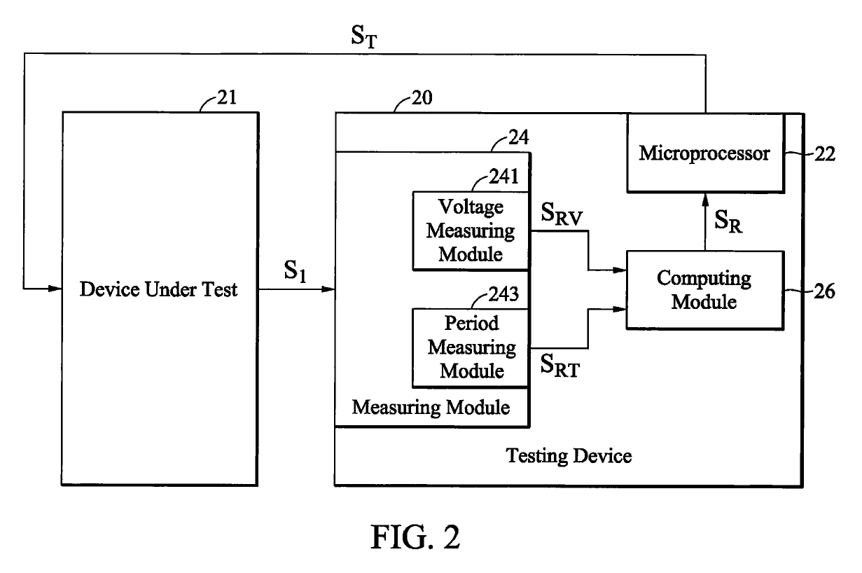

Please refer to FIG. 2. FIG. 2 is a schematic diagram of the testing device testing the device under test according to an embodiment of the invention. As shown in FIG. 2, a device under test 21 is tested by the testing device 20 according to an embodiment of the invention. In an embodiment, the testing device 20 of the invention includes a logic tester, and the device under test 21 includes an integrated circuit.

The testing device 20 comprises a microprocessor 22, a measuring module 24 and a computing module 26. The microprocessor 22 provides a testing signal S_{T} to the device under test 21. The device under test 21 further generates at least one measuring signal S_{T} after receiving the testing signal, and determines a testing result for the device under test 21 according to at least one signal measurement result S_{R}. The measuring module 24 coupled to the device under test 21 measures at least one measuring signal S₁ output by the device under test 21, and generates at least one voltage measurement result S_{RV} and at least one period measurement result S_{RT}, The computing module 26 coupled to the measuring module 24 computes the at least one voltage measurement result S_{RV} and the at least one period measurement result S_{RT} according to a predetermined manner and generates the at least one signal measurement result S_{R}.

The measuring module 24 comprises a voltage measuring module 241 and a time measuring module 243. The voltage measuring module 241 measures the voltage value of the at least one measuring signal S₁ to generate the at least one voltage measurement result S_{RV}. And the time measuring module 243 measures the period value of the at least one measuring signal S₁ to generate the at least one period measurement result S_{RT}.

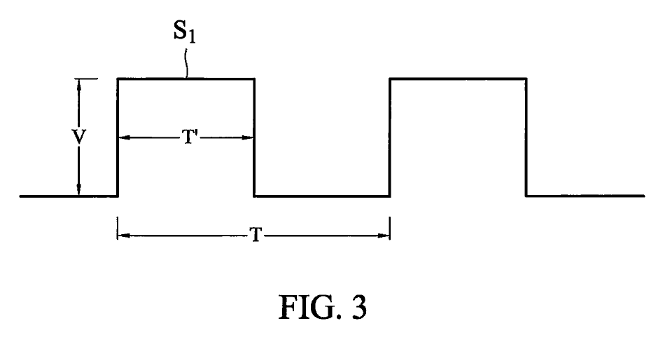

Please refer to FIG. 2 and FIG. 3. FIG. 3 shows a diagram of at least one measuring signal of the testing device according to an embodiment of the invention. As shown in FIG. 2 and FIG. 3, the at least one voltage measurement result S_{RV} comprises a voltage value V and the at least one period measuring value S_{RT} comprises a period T and a first time period T′. The first time period T′ represents the time period remaining a first logic state during the period T of the at least one measuring signal S₁. In an embodiment, the first logic state is a high logic level. Thus, the first time period T′ represents the time period remaining in the high logic level during the period T. In this embodiment, the time period and voltage of the at least one measuring signal S₁ are tested.

In an embodiment, an average voltage outputted from the device under test 21 is tested by the testing device 20. In an embodiment of the invention, the computing module 26 calculates the at least one voltage measurement result S_{RV} and the at least one period measurement result S_{RT} by a formula as below for generating the at least one measuring signal S_{R}:

$$Va = \frac{V * {T}^{′}}{T} ;$$

wherein Va represents an average voltage value, V represents the voltage value of the at least one measuring signal S₁, T represents the total period of the at least one measuring signal S₁, T′ represents the first time period of the at least one measuring signal S₁, and wherein at least one measuring signal S_{R} represents the average voltage value.

After the computing module 26 outputs the average voltage value generated by the predetermined manner to the microprocessor 22, the microprocessor 22 determines whether the device under test 21 passes or fails the test process based on the output of the average voltage value.

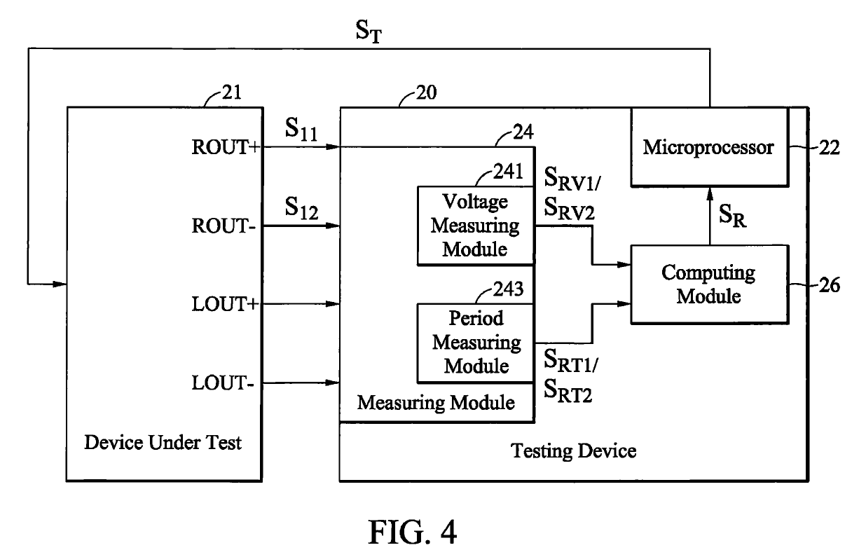

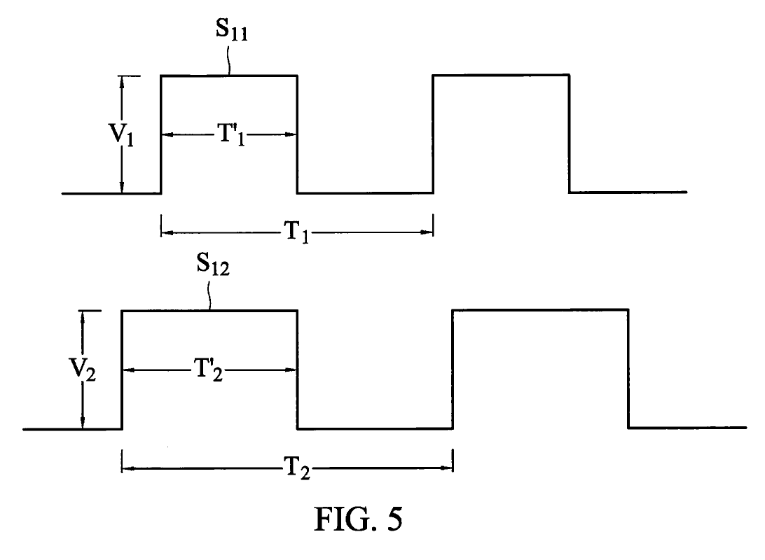

Please refer to FIG. 4 and FIG. 5. FIG. 4 is a schematic diagram of the testing device testing the device under test according to another embodiment of the invention. FIG. 5 is a schematic diagram of the first measuring signal and the second measuring signal of the testing device according to an embodiment of the invention. In an embodiment, the device under test 21 is a D-type amplifier IC. A first measuring signal S₁₁ and a second measuring signal S₁₂ representing the differential output signals of the output ports ROUT+and ROUT− of the right sound channel, respectively. In an embodiment, after the at least one measuring signal S_{T} is received by the device under test 21, a first measuring signal S₁₁ and the second measuring signal S₁₂ are generated from the device under test 21 and measured by the measuring module 24 to generate a first voltage measurement result S_{RV1}, a second voltage measurement result S_{RV2}, a first period measurement result S_{RT1} and a second period measurement result S_{RT2}. The first voltage measurement result S_{RV1} comprises a first voltage value V1, the second measurement result S_{RV2} comprises a second voltage value V2, and the first period measurement result S_{RT1} comprises a first period T1 and a first time period T′₁. The first time period T′₁ represents the time period during a first logic state period in the at least one measuring signal S₁₁. The second period measurement result S_{RT2} comprises a second period T2 and a second time period T′₂. The second time period T′₂ represents the time period during a first logic state period in the at least one measuring signal S₁₂. In an embodiment, the first logic state is a high logic level.

In an embodiment, the testing device 20 tests a voltage offset of the device under test 21. In the embodiment of the invention, the computing module 26 calculates the first voltage measurement result S_{RV1}, the second voltage measurement result S_{RV2}, the first period measurement result S_{RT1}, and the second period measurement result S_{RT2} by a formula as below for generating the at least one measuring signal S_{R}:

V_{offset}=[V₁*T′₁/T₁]−[V₂*T′₂/T₂];

wherein V_{offset} represents a voltage offset, V1 represents the first voltage value, V2 represents the second voltage value, T′₁ represents the first time period, T′₂ represents the second time period, T1 represents a first period, T2 represents a second period. At least one signal measurement result S_{R} represents the voltage offset. After receiving the V_{offset} from the computing module 26, the microprocessor 22 determines whether the device under test 21 has passed or failed the test.

In another embodiment, the testing device 20 tests a voltage offset of the device under test 21. The computing module 26 calculates the first voltage measurement result S_{RV1}, the second voltage measurement result S_{RV2}, the first period measurement result S_{RT1} and the second period measurement result S_{RT2} by a formula as below for generating the at least one measuring signal S_{R}:

$$Gain = \frac{[ {V}_{1} * {T}_{1}^{′} / {T}_{1} ] - [ {V}_{2} * {T}_{2}^{′} / {T}_{2} ]}{Vin} ;$$

wherein Gain represents voltage gain, Vᵢₙ represents an input voltage of a measuring signal, V₁ represents the first voltage value, V₂ represents the second voltage value, T′₁ represents the first time period, T′₂ represents the second time period, T₁ represents a first period, and T₂ represents a second period. After receiving the voltage gain from the computing module 26, the microprocessor 22 then determines whether the device under test 21 has passed or failed the test.

Additionally, the testing device 20 further comprises a register (not shown) for storing the testing result of the device under test 21. Testing results of each device under test 21 can be stored in the register (not shown) entirely when a plurality of devices under test 21 are tested by the testing device 20 at the same time. The testing results are accessed from the register (not shown) to determine whether the plurality of devices under test 21 have passed or failed the test. Thus, the testing device of the present invention can reduces testing time and enhances testing efficiency. The testing device 20 further comprises a display module which is coupled to the microprocessor, wherein the display module is configured to display the testing result of the device under test 21.

According to the embodiments of the invention, the first time period, the period and the voltage value of the at least one measuring signal, which were generated from the devices under test (for example a D-type amplifier IC), were tested using the logic tester. Then, the testing results were generated from the computing module according different manners, such as calculating the average voltage, the voltage gain, and the Voffset, etc. On the contrary, the conventional art requires appropriate logic testers (such as, audio logic tester) to test the device under test. The testing device according to the embodiments of the invention not only increases testing speed but also decreases testing costs, improving upon the prior art.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A testing device for testing a device under test, comprising:
a microprocessor providing a testing signal to said device under test, and determining a testing result for said device under test according to at least one signal measurement result, wherein said device under test generates at least one measuring signal after receiving said testing signal;
a measuring module coupled to said device under test for measuring said at least one measuring signal to generate at least one voltage measurement result and at least one period measurement result; and
a computing module coupled to said measuring module for computing said at least one voltage measurement result and said at least one period measurement result according to a predetermined manner to generate said at least one signal measurement result.

2. The testing device as claimed in claim 1, wherein said measuring module comprises:
a voltage measuring module for measuring at least one voltage value of said at least one measuring signal to generate said at least one voltage measurement result; and
a time measuring module for measuring at least one period of said at least one measuring signal to generate said at least one period measurement result.

3. The testing device as claimed in claim 2, wherein said at least one voltage measurement result includes a voltage value, and wherein said at least one period measurement result includes a period value.

4. The testing device as claimed in claim 3, wherein said at least one period measurement result further includes a first time period, and said first time period represents the time period during a first logic state period in said at least one measuring signal.

5. The testing device as claimed in claim 4, wherein said first logic state is a high logic level.

6. The testing device as claimed in claim 4, wherein said predetermined manner is to calculate said at least one voltage measurement result and said at least one period measurement result by a formula as below for generating said at least one measuring signal:
$$Va = \frac{V * {T}^{′}}{T} ;$$
wherein Va represents an average voltage value, V represents said voltage value of said at least one measuring signal, T represents the total period of said at least one measuring signal, and T′ represents said first time period of said at least one measuring signal.

7. The testing device as claimed in claim 6, wherein said at least one measuring signal is said average voltage value.

8. The testing device as claimed in claim 2, wherein a first measuring signal and a second measuring signal are generated after said at least one measuring signal is received by said device under test, and said measuring module measures said first measuring signal and said second measuring signal to generate a first voltage measurement result, a second voltage measurement result, a first period measurement result and a second period measurement result.

9. The testing device as claimed in claim 8, wherein said first voltage measurement result includes a first voltage value (V1), said second measurement result includes a second voltage value (V2), said first period measurement result includes a first period (T1) and said first period measurement result includes a second period (T2).

10. The testing device as claimed in claim 9, wherein said first period measurement result further includes a first time period (T′₁), said first time period represents the time period during a first logic state period in said at least one measuring signal, and said at least one period measurement result further includes a second time period (T′₂), wherein said second time period represents the time period during a first logic state period in said at least one measuring signal.

11. The testing device as claimed in claim 10, wherein said first logic state is a high logic level.

12. The testing device as claimed in claim 10, wherein said predetermined manner is to calculate said first voltage measurement result, said second voltage measurement result, said first period measurement result and said second period measurement result by a formula as below for generating said at least one measuring signal.
V_{offset}=[V₁*T′₁/T₁]−[V₂*T′₂/T₂],
wherein V_{offset} represents a voltage offset, V1 represents said first voltage value, V2 represents said second voltage value, T′₁ represents said first time period, T′₂ represents said second time period, T1 represents a first period, and T2 represents a second period.

13. The testing device as claimed in claim 10, wherein said at least one signal measurement result is said voltage offset.

14. The testing device as claimed in claim 10, wherein said predetermined manner is said computing module calculating said first voltage measurement result, said second voltage measurement result, said first period measurement result and said second period measurement result by a formula as below for generating said at least one measuring signal:
$$Gain = \frac{[ {V}_{1} * {T}_{1}^{′} / {T}_{1} ] - [ {V}_{2} * {T}_{2}^{′} / {T}_{2} ]}{Vin} ,$$
wherein Gain represents voltage gain. Vin represents an input voltage of a measuring signal, V1 represents said first voltage value, V2 represents said second voltage value, T′₁ represents said first time period, T′₂ represents said second time period, T1 represents a first period, and T2 represents a second period.

15. The testing device as claimed in claim 14, wherein said at least one signal measurement result is voltage gain.

16. The testing device as claimed in claim 1, further comprising a register coupled to said microprocessor for storing said testing result.

17. The testing device as claimed in claim 1, wherein said testing device includes a logic tester.

18. The testing device as claimed in claim 1, wherein said device under test is an integrated circuit (IC).

19. The Said testing device as claimed in claim 1, wherein said device under test is a D-type amplifier integrated circuit (IC).

20. The testing device as claimed in claim 1, further comprising a display module coupled to said microprocessor to display said testing result of said device under test.
